(19) United States
(12) Patent Application Publication
(10) Pub. No.: US 2024/0291072 A1
(43) Pub. Date: Aug. 29, 2024

(54) THERMAL REGULATION DEVICE FOR ELECTRONIC SYSTEM

(71) Applicant: Valeo Systemes Thermiques, Le Mesnil-Saint-Denis (FR)

(72) Inventors: Bastien Jovet, Le Mesnil-Saint-Denis (FR); Lionel Robillon, Le Mesnil-Saint-Denis (FR); Fabienne Tourneux, Le Mesnil-Saint-Denis (FR); Mohamed Ibrahimi, Le Mesnil-Saint-Denis (FR); Juan-Carlos Batista, Le Mesnil-Saint-Denis (FR)

(73) Assignee: Valeo Systemes Thermiques, Le Mesnil-Saint-Denis (FR)

(21) Appl. No.: 18/573,070

(22) PCT Filed: Jun. 14, 2022
(86) PCT No.: PCT/EP2022/066225

§ 371 Date: Dec. 21, 2023

(30) Foreign Application Priority Data
Jun. 22, 2021 (FR) 2106644

(51) Int. Cl. H01M 10/6568; H01M 10/625; H01M 10/6557

(52) U.S. Cl. CPC H01M 10/6568; H01M 10/6557; H01M 10/625

(57) ABSTRACT

A thermal control device for an electronic system is disclosed. The thermal control device includes a box configured to accommodate electrical and/or electronic components of the electronic system. The box includes a bottom wall and side walls opposite in pairs that altogether define an inner housing. The inner housing is able to receive the electrical and/or electronic components. The outer faces of the side walls are defined as those facing away from the inner housing. The box includes thermal control fluid supply and discharge elements. The supply element and discharge element are in fluid communication with the inner housing. The supply element and discharge elements respectively project from one of the outer faces of the side walls of the box. The supply and discharge elements are arranged on the side walls at different distances from the bottom wall.

The present invention relates to the field of thermal control devices for electrical or electronic components, and it relates more particularly to a thermal control device for an electronic system equipped with electrical and/or electronic components capable of heating up during their operation.

The electronic systems which may be concerned by the present invention may consist of computer servers as well as electrical energy storage systems for motor vehicles, and more particularly for hybrid or electric vehicles.

The electric drives of such vehicles use electronic systems that can take the form of batteries, which undergo successive phases of electric charging and discharging and which need to be thermally controlled in order to protect the components they comprise. When these electronic systems heat up, for example during a rapid charge, it is therefore important to be able to cool them quickly and efficiently, so as to preserve their efficiency.

Thermal control devices can thus be associated with these batteries, to modify a temperature of an electric battery, whether during a cold weather start of the vehicle, for example by increasing its temperature, or whether during driving or during a battery recharging operation, by reducing the temperature of this electric battery, which tends to heat up during its use.

In general, thermal control devices of this type for electric batteries use heat exchangers. In particular, the different battery cells of an electrical storage system can be cooled by means of a cold plate inside which a thermal control fluid circulates, the plate being in contact with the battery cells to be cooled. It has been found that such heat exchangers can lead to nonhomogeneous cooling of the electric batteries of the same electrical storage system, resulting in a decrease in the overall performance of the electrical storage system. These thermal control devices also have high thermal resistance owing to the material thicknesses present between the thermal control fluid and the battery cells.

In order to provide an answer to these different problems, devices for cooling electric battery elements of electric or hybrid cars are known, comprising a hermetically sealed housing in which the battery elements of the electrical energy storage system are partially immersed in a dielectric thermal control fluid. Heat exchange between the battery elements and the dielectric fluid is thus ensured, a dielectric fluid vessel being situated outside the housing and connected to said housing via a pump to allow the dielectric fluid to circulate and this dielectric thermal control fluid to be renewed within the housing. In this way, the dielectric thermal control fluid, put into motion and cooled prior to its return into the housing, is also able to circulate inside the housing around the electrical storage cells. However, it should be noted that, when the cooled dielectric fluid is put into motion by the pump, the storage cells which are positioned furthest from the intake of dielectric fluid into the housing are less well cooled by exchange of heat with the dielectric fluid than the storage cells which are situated closest to the dielectric fluid intake, such that the cooling of the electrical or electronic components is not carried out homogeneously.

In order to carry out the circulation of the dielectric thermal control fluid, it is known to associate with the housing supply elements and discharge elements fluidically connected inside the housing and forming projections on walls of the housing. These supply and discharge elements must therefore be considered within the overall size of each thermal control device and they are particularly detrimental in terms of overall size when it is necessary to arrange a plurality of thermal control devices side by side, whether for storage considerations during transport, for example, or for considerations of optimizing the size of the electronic system when this electronic system requires the presence of a large number of electrical and/or electronic components and therefore a plurality of thermal control devices.

The present invention falls within this context by proposing a thermal control device for an electronic system comprising a box configured to accommodate electrical and/or electronic components of said electronic system, this box having a bottom wall and side walls opposite in pairs defining an inner housing able to receive the electrical and/or electronic components, the outer faces of these side walls being defined as those facing away from the inner housing, this box comprising at least one thermal control fluid supply element, at least one thermal control fluid discharge element, this supply element and this discharge element being in communication with the inner housing, the supply element and the discharge element respectively projecting from one of the outer faces of the side walls of the box, characterized in that the supply element and the discharge element are arranged on the side walls at different distances from the bottom wall.

This thermal control device is therefore configured in such a way that all electrical and/or electronic components can be at least partially immersed in the thermal control fluid. The presence of the thermal control fluid is ensured by means of at least one supply element, by means of which the thermal control fluid enters the box and more particularly the inner housing, and the renewal of the thermal control fluid within the inner housing, in order to be able to maintain an appropriate temperature of the thermal control fluid of at least one discharge element for this fluid. These elements are arranged on the walls of the box of the thermal control device in such a way that the thermal control of the electrical and/or electronic components is optimized, the thermal control fluid being able to flow uniformly between each electrical and/or electronic component.

Moreover, this arrangement of the supply and discharge elements has the effect of facilitating the arrangement of adjacent boxes. Since the positioning of these elements allows the thermal control devices to be nested laterally one inside the other, these devices can be arranged side by side with a reduced bulk.

According to one embodiment of the invention, the supply element projects from the outer face of a side wall of the box and the discharge element projects from the outer face of an opposite side wall of the box.

According to an alternative embodiment, the supply element and the discharge element project from the outer face of the same side wall of the box.

According to one feature of the invention, the supply element is separated from the bottom wall by a distance greater than the distance separating the discharge element from the bottom wall.

According to another feature of the invention, the supply element comprises a duct extending mainly along a longitudinal direction, this duct being delimited longitudinally by two walls, among which a first wall, in the vicinity of a first longitudinal end of the box, bears an end piece, the duct having a cross section, in a plane perpendicular to the longitudinal direction, that decreases progressively away from the first wall.

The reduction in the cross section of the duct of the supply element makes it possible, in particular, for the thermal control fluid flowing through it to be distributed uniformly within the inner housing in which the electrical and/or electronic components are arranged. Specifically, this reduction causes the thermal control fluid to accelerate as it advances through the duct, thus ensuring homogeneous propagation from one longitudinal end of the thermal control device to the other.

According to another feature of the invention, the discharge element comprises a duct extending mainly along a longitudinal direction, this duct being delimited longitudinally by two walls, among which a first wall, in the vicinity of the first longitudinal end of the box, bears an end piece, the duct having a cross section, in a plane perpendicular to the longitudinal direction, that decreases progressively away from the first wall.

According to an alternative feature, the discharge element comprises a duct extending mainly along a longitudinal direction, this duct being delimited longitudinally by two walls, among which a first wall, in the vicinity of a second longitudinal end of the box opposite the first longitudinal end of the box, bears an end piece, the duct having a cross section, in a plane perpendicular to the longitudinal direction, that widens progressively away from the first wall.

According to one feature of the invention, the duct forms a projection which has, in a plane perpendicular to the longitudinal direction, a U-shape open onto the inner housing of the box.

According to one embodiment of the invention, the box comprises a base and a cover, the base being constituted by the bottom wall and the side walls, this base being formed in one piece.

The base of the box then forms a one-piece assembly so that the bottom wall cannot be separated from the side walls without damaging one or the other. This one-piece assembly can in particular be obtained by additive manufacturing, for example by 3D printing. Since only one manufacturing operation is required, this embodiment offers ease of manufacture as well as a saving of time and reduced costs.

According to an alternative embodiment of the invention, the box comprises a base and a cover, the base being constituted by the bottom wall and the side walls, this base being formed by a first element comprising the bottom wall and two opposite side walls, the other two side walls being attached and fixed to the first element.

More particularly, the first element of the base may be formed by the bottom wall and transversely opposite side walls which bear the supply and discharge elements, the other two side walls being attached to the first element to close the inner housing in a second step. This embodiment requires several manufacturing operations; the base may for example be formed by stamping, then the other side walls are fixed by brazing on this base.

According to one feature of the invention, the box is made of a material chosen for its thermal insulation properties.

In particular, this material chosen for its thermal insulation properties can be a plastics material.

Even more particularly, the plastics material can be organosheet.

According to an alternative feature of the invention, at least the bottom wall and the walls bearing the supply element and the discharge element are made of metal.

Advantageously, this metal may be aluminum.

The invention also relates to an electronic system comprising a thermal control device as mentioned above and electrical and/or electronic components housed in the box, and wherein the electrical and/or electronic components are separated from at least one electrical and/or electronic component by a separating member.

This separating member acts as a spacer, which allows two elements to be spaced apart. The separating member may for example be a corrugated metal sheet, which defines fluid passage channels along each of the electrical and/or electronic components arranged on either side of this separating member.

According to one feature of the invention, the separating member is configured to allow the thermal control fluid to pass between two electrical and/or electronic components.

For example, the electrical and/or electronic components are separated by a distance of between 0.2 and 1 mm by the separating member.

According to another optional feature of the invention, the electronic system comprises a sealing element configured to be arranged between the electrical and/or electronic components and the walls.

According to one feature of the invention, the sealing element is arranged in the vicinity of the vertical end of the electrical and/or electronic components that is opposite the bottom wall, this vertical end extending in a direction orthogonal to the bottom wall.

This particular arrangement of the sealing element makes it possible to avoid immersion of the connection elements of the electrical and/or electronic components in the thermal control fluid, these connection elements being arranged on the vertical end of the electrical and/or electronic components.

Other features, details and advantages of the invention will become more clearly apparent on reading the following description, on the one hand, and exemplary embodiments given by way of nonlimiting indication with reference to the accompanying drawings, on the other hand, in which drawings:

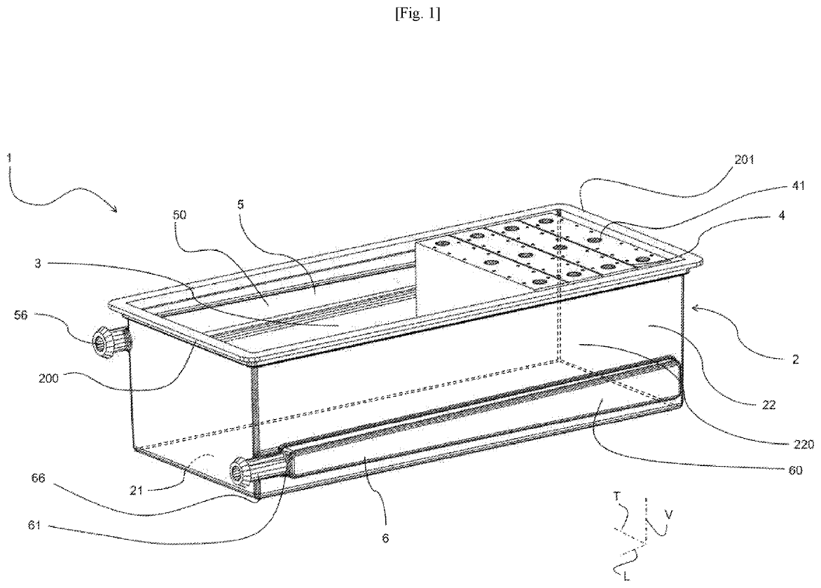

FIG. 1 illustrates, schematically, a perspective view of a thermal control device for an electronic system, here electrical energy storage elements partially represented, according to the invention;

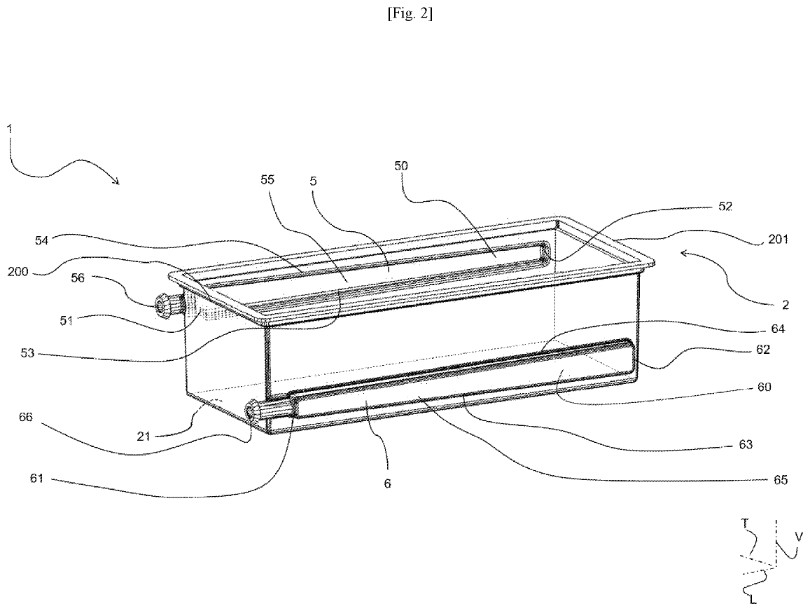

FIG. 2 illustrates, schematically, a perspective view of part of the thermal control device of FIG. 1;

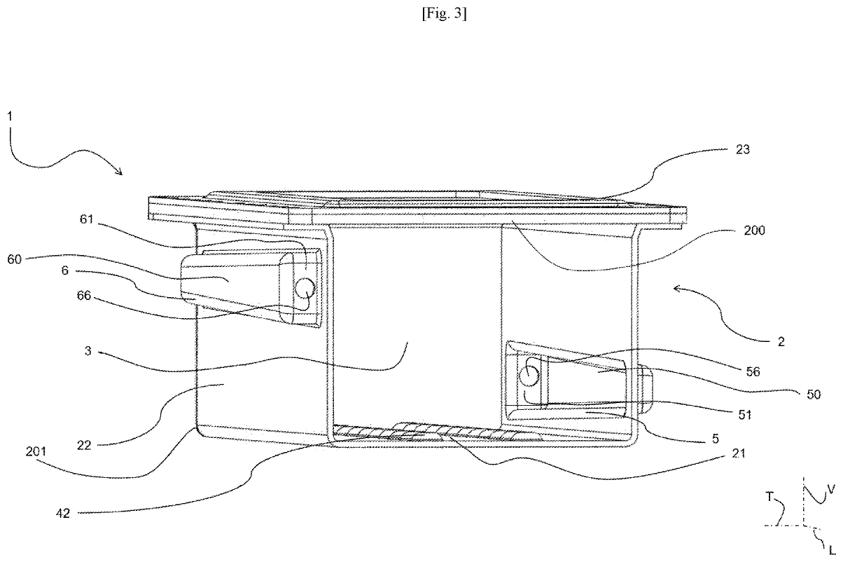

FIG. 3 illustrates, schematically, a perspective view of the thermal control device according to an alternative embodiment of the invention;

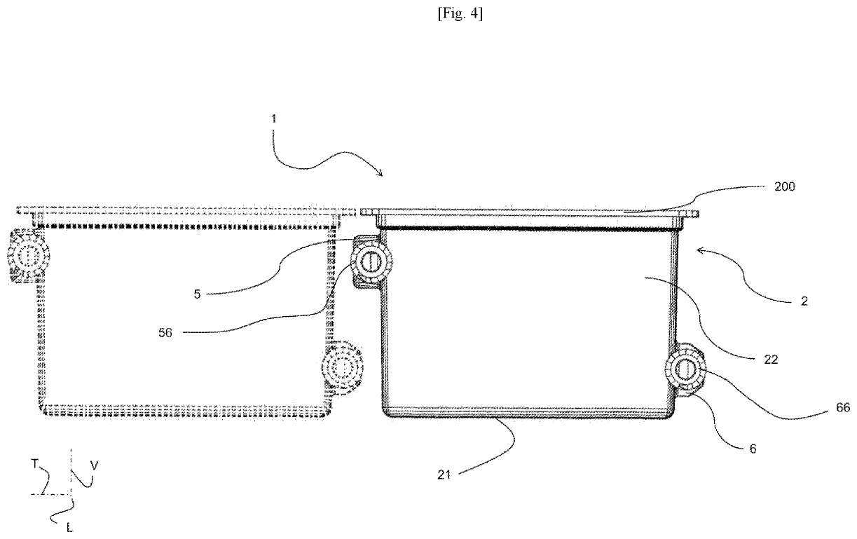

FIG. 4 illustrates, schematically, an arrangement of two thermal control devices according to the invention, with supply and discharge ducts for thermal control fluid arranged on opposite side walls of the same thermal control device;

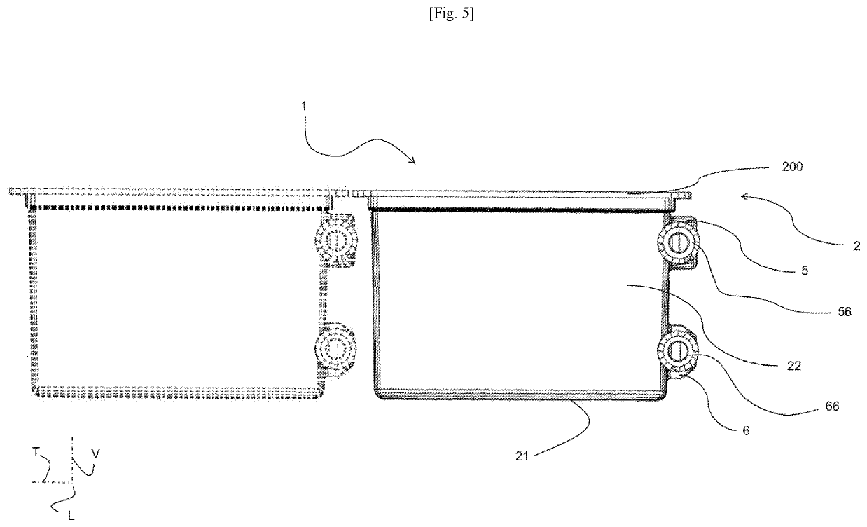

FIG. 5 illustrates, schematically, a front view of a variant of the arrangement of FIG. 4, with two thermal control devices according to the invention which each have ducts for supplying and discharging thermal control fluid arranged on the same side wall;

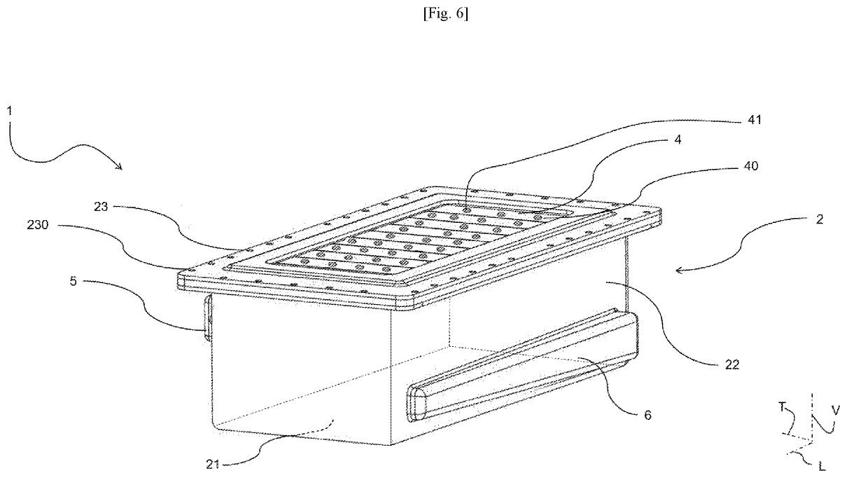

FIG. 6 illustrates, schematically, a perspective view of the thermal control device of FIG. 3;

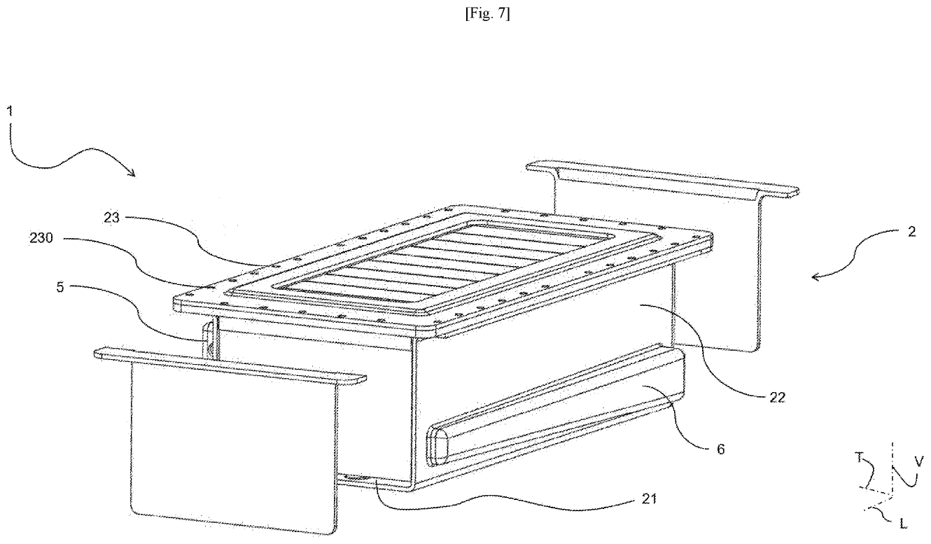

FIG. 7 illustrates, schematically, a representation of an alternative to the thermal control device illustrated in FIG. 6;

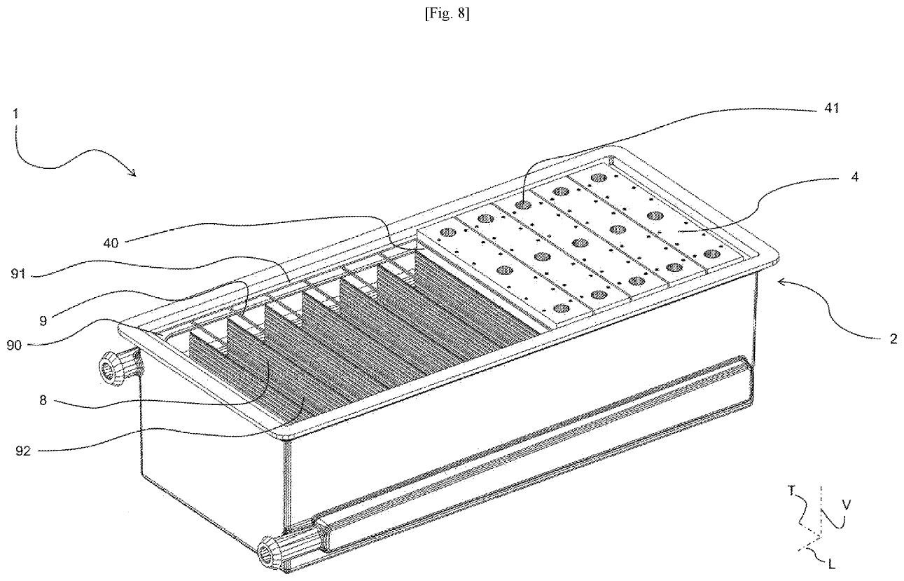

FIG. 8 illustrates, schematically, a perspective view of a thermal control device according to the invention, equipped here with a sealing means;

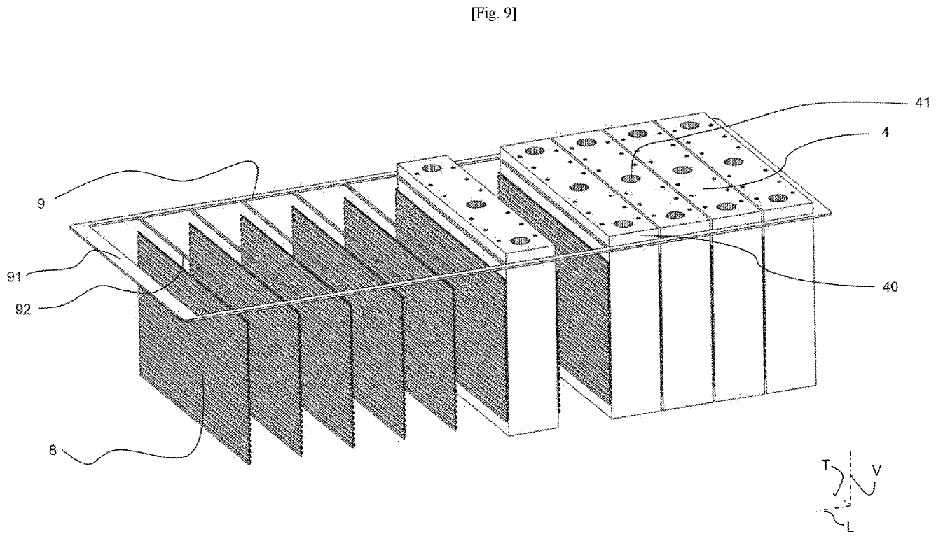

FIG. 9 illustrates, schematically, the thermal control device of FIG. 8, the box having been erased to reveal the components located inside it.

The features, variants and various embodiments of the invention may be combined with one another, in various combinations, as long as they are not mutually incompatible or mutually exclusive. It will be possible, in particular, to imagine variants of the invention that comprise only a selection of the features described below, in isolation from the other features described, if this selection of features is sufficient to confer a technical advantage and/or to distinguish the invention from the prior art.

In the figures, elements that are common to multiple figures retain the same reference.

In the detailed description which follows, the denominations “longitudinal”, “transverse” and “vertical” refer to the orientation of the thermal control device according to the invention. A longitudinal direction corresponds to a main direction of elongation of the box of the thermal control device, this longitudinal direction being parallel to a longitudinal axis L of a reference frame L, V, T illustrated in the figures. A transverse direction corresponds to a direction in which the electrical and/or electronic components mainly extend, this transverse direction being parallel to a transverse axis T of the reference frame L, V, T and this transverse axis T being perpendicular to the longitudinal axis L. Finally, a vertical direction corresponds to a direction parallel to a vertical axis V of the reference frame L, V, T, this vertical axis V being perpendicular to the longitudinal axis L and to the transverse axis T.

In addition, in the present description, the term “thermal control fluid” may refer to any heat-transfer, dielectric, two-phase or refrigerant fluid or liquid, provided that this fluid or liquid has the effect of cooling the electrical and/or electronic components of a thermal control device.

In addition, in the following detailed description, the thermal control device according to the invention will be described in relation to an electronic system in the form of a motor vehicle electrical energy storage system, but it should be understood that an application of this type is nonlimiting, and that in particular it could be applied within the context of the invention to electrical or electronic components which equip other electronic systems, and for example computer servers.

FIG. 1 thus schematically illustrates a perspective view of a thermal control device 1 according to the invention, configured to modify the temperature, particularly by cooling, of electrical and/or electronic components which are here cells of an electric battery module for a hybrid or electric vehicle. This thermal control device 1 comprises a box 2 elongated mainly in a longitudinal direction between a first longitudinal end 200 of the box 2 and a second longitudinal end 201 of the box 2. The box 2 comprises a bottom wall 21 and four side walls 22 opposite in pairs, these walls delimiting an inner housing 3 configured to accommodate the electrical and/or electronic components 4. A portion of these electrical and/or electronic components 4 has been removed from the illustration shown in FIG. 1 in order to allow a better view of the other components of the thermal control device 1.

The electrical and/or electronic components 4 are arranged side by side along the longitudinal direction of the box 2, being arranged parallel to one another here, perpendicular to the longitudinal direction of the box. At least one of the faces of an electrical and/or electronic component 4 extending in a vertical and transverse plane, perpendicular to the longitudinal direction of the box, is opposite one of the faces, extending in a vertical and transverse plane, of an adjacent electrical and/or electronic component 4. Each electrical and/or electronic component 4 is arranged at a distance from the adjacent electrical and/or electronic component 4, and at a distance from the side walls 22 which delimit the inner housing 3, so as to define spacings between each electrical and/or electronic component. These spacings in particular allow the thermal control fluid to circulate between the electrical and/or electronic components 4 and between the electrical and/or electronic components 4 and the side walls 22, this ensuring optimum thermal control of each of the electrical and/or electronic components within the thermal control device 1.

The electrical and/or electronic components 4 have, on a vertical end face 40 which extends away from the bottom wall, connection elements 41 for connecting the electrical and/or electronic components to an electrical supply and/or distribution network of the vehicle.

The side walls 22 of the box 2 have outer faces 220, these outer faces 220 of the side walls 22 being defined as those which face away from the inner housing 3.

In order to allow a circulation of thermal control fluid within the thermal control device, and a renewal of this thermal control fluid in order to facilitate the exchange, and in particular the discharge, of heat from the box 2 of the thermal control device 1, the box 2 comprises at least one thermal control fluid supply element 5 and at least one thermal control fluid discharge element 6, these supply 5 and discharge 6 elements being in communication with the inner housing 3. The thermal control fluid supply element 5 and the thermal control fluid discharge element 6 respectively project from one of the outer faces 220 of the side walls 22 of the box 2.

According to the invention, this supply element 5 and this discharge element 6 are arranged on the side walls 22 at different distances from the bottom wall 21. It will thus be understood that the thermal control fluid supply element 5 may be arranged on an outer face 220 at a distance from the bottom wall 21 greater than the distance separating the thermal control fluid discharge element 6 from this bottom wall 21, as shown in FIG. 1, or conversely that the thermal control fluid discharge element 6 may be arranged on an outer face 220 at a distance from the bottom wall 21 greater than the distance separating the thermal control fluid supply element 5 from this bottom wall 21.

The thermal control fluid supply element 5 and the thermal control fluid discharge element 6 each comprise a duct 50, 60 along which the thermal control fluid is able to circulate in order to enter or leave the box 2.

The supply duct 50 of the thermal control fluid supply element 5 and the discharge duct 60 of the thermal control fluid discharge element 6 respectively form a U-shaped projection on one of the outer faces 220 of the side walls 22, this projection being open onto the inner housing 3 of the box 2. The projection formed by these ducts 50, 60 is said to be U-shaped in that, in a cross-sectional plane perpendicular to the side wall 22, the profile of the duct 50, 60 is open onto the housing, a fluidic communication being formed between the duct 50, 60 and the inner housing 3 via an opening formed in the corresponding side wall 22, said opening extending over substantially the entire longitudinal dimension of the duct 50, 60.

As illustrated in FIG. 2, in which the electrical and/or electronic components 4 have been removed from the box 2, the thermal control fluid supply element 5 and the thermal control fluid discharge element 6 are respectively formed by the ducts 50, 60, which are produced here by deformations of the side walls 22 to form the U-shaped projections, and by end pieces 56, 66. These ducts 50, 60 are configured to allow longitudinal circulation of the thermal control fluid and homogeneous distribution for each of the electrical and/or electronic components arranged in the inner housing 3.

The end pieces 56 and 66 are respectively situated, according to the embodiment shown in FIG. 2, on first longitudinal end walls 51, 61 of each of the ducts, these first longitudinal end walls being in the vicinity of the first longitudinal end 200 of the box 2. These first longitudinal end walls 51, 61 define one longitudinal end of the ducts 50, 60, the other longitudinal end corresponding to second longitudinal end walls 52, 62 situated in the vicinity of the second longitudinal end 201 of the box 2. The first longitudinal end walls 51, 61 and the second longitudinal end walls 52 and 62 are substantially parallel to one another, and are substantially perpendicular to the side walls 22 which support the thermal control fluid supply element 5 and the thermal control fluid discharge element 6.

Furthermore, the ducts 50, 60 are respectively delimited vertically by lower walls 53, 63 and by upper walls 54, 64, the lower walls 53, 63 being defined as those which have a distance from the bottom wall 21 less than the distance separating the upper walls 54, 64 from this bottom wall 21.

Transverse walls 55, 65, substantially parallel to the side walls 22 which bear the thermal control fluid supply element 5 and the thermal control fluid discharge element 6, respectively delimit the ducts 50, 60 in a transverse direction.

It will therefore be understood that the supply duct 50 of the thermal control fluid supply element 5 is delimited longitudinally by the first longitudinal end wall 51 and the second longitudinal end wall 52, vertically by the lower wall 53 and the upper wall 54, and transversely by the transverse wall 55. The same delimitation is applicable mutatis mutandis to the discharge duct 60 of the thermal control fluid discharge element 6.

In the example illustrated in FIG. 2, with the end piece 56 of the supply duct 50 of the thermal control fluid supply element 5 being arranged on the first longitudinal end wall 51, it is therefore in the vicinity of the first longitudinal end 200 of the box 2. In the same way, the end piece 66 of the discharge duct 60 of the thermal control fluid discharge element 6 is in the vicinity of the first longitudinal end 200 of the box 2.

The supply duct 50 has a cross section that decreases progressively away from the first longitudinal end wall 51, and therefore progressively away from the first longitudinal end 200 of the box 2. The reduction in cross section is understood here in particular by a reduction in the height of the supply duct 50, this height being defined as the vertical dimension of the supply duct 50 which is measured between the lower wall 53 and the upper wall 54. This height of the supply duct 50 is therefore greater in the vicinity of the first longitudinal end wall 51 than of the second longitudinal end wall 52.

Conversely, the discharge duct 60 has a cross section that widens progressively away from the first wall 61, and therefore progressively away from the first longitudinal end 200 of the box 2. The enlargement in cross section is understood here in particular by an increase in the height of the discharge duct 60, this height being defined as the dimension of the discharge duct 60 which is measured between the lower wall 63 and the upper wall 64. This height of the discharge duct 60 is therefore greater in the vicinity of the first longitudinal end wall 61 than of the second longitudinal end wall 62.

The characteristics of the ducts 50, 60 according to which they have a cross section that decreases or a cross section that widens from the corresponding end piece make it possible to change the flow cross section available for the thermal control fluid within the corresponding duct. In this way, the reduction in the flow cross section of the supply duct 50 makes it possible to force the thermal control fluid to accelerate and to circulate as far as the longitudinal end opposite the inlet end piece of this supply duct 50, this making it possible to ensure that the thermal control fluid circulates up to the end of the supply duct and is distributed homogeneously within the inner housing 3, and therefore between the electrical and/or electronic components 4 and around them. Similarly, the increase in the flow cross section of the discharge duct 60 makes it possible to cause more thermal control fluid to enter the discharge duct 60 in a zone remote from the end piece 66 through which the thermal control fluid leaves the box 2. This ensures that the renewal of the thermal control fluid is homogeneous over the entire longitudinal dimension of the box 2.

A homogeneous distribution of the thermal control fluid between the electrical and/or electronic components 4 within the inner housing 3 is also ensured by the fact that, when the thermal control fluid supply duct 50 has a cross section that decreases progressively away from the first longitudinal end 200 of the box 2 and when the thermal control fluid discharge duct 60 has a cross section that widens progressively away from this first longitudinal end 200, the cross section where the height of the supply duct 50 is at a maximum is placed opposite, through the inner housing 3, to the cross section where the height of the discharge duct 60 is at a minimum, when these heights are measured at the same longitudinal distance from the first longitudinal end 200 or from the second longitudinal end 201. Conversely, the cross section where the height of the supply duct 50 is at a minimum is placed opposite, through the inner housing 3, to the cross section where the height of the discharge duct 60 is at a maximum. The supply duct 50 and the discharge duct 60 therefore have variations in their cross sections in opposition, which contributes to facilitating the circulation of the fluid between the electrical and/or electronic components 4 from one duct to the other and homogeneously over the entire longitudinal dimension of the box. The thermal control fluid is attracted to the region of the discharge duct 60 where the height of the cross section is at a maximum, and to arrive in this region, it tends to circulate in the supply duct 50 as far as a facing region and therefore as far as a region of the supply duct 50 where the height of the cross section is at a minimum, which contributes to pushing the fluid up to the end of the supply duct 50.

Alternatively, provision can be made for the discharge duct 60 of the thermal control fluid discharge element 6 to be equipped with an end piece 66 which is arranged in the vicinity of the second longitudinal end 201 of the box 2. In this alternative, it should be noted that the shape of the discharge duct would remain the same so that the cross section of largest diameter would be arranged close to this second longitudinal end 201, and that, consequently, the cross section of the discharge duct would be reduced progressively away from the end piece.

Such an alternative is illustrated in particular in FIG. 3, in which the side wall 22 situated at the first longitudinal end 200 of the box 2 has been removed, and in which the inner housing 3 is devoid of any electrical and/or electronic component 4, in order to make visible the inside of the box 2 and the fluidic communication between the inner housing 3 and one of the ducts, in this case the discharge duct 60.

The box 2 comprises a cover 23 which closes the inner housing 3 defined by the side walls 22. This cover 23 rests on a rim formed by a vertical end of these side walls 22 away from the bottom wall, this rim extending toward the outside of the inner housing 3. The cover 23 extends from the first longitudinal end 200 of the box 2 to the second longitudinal end 201 of the box 2, substantially parallel to the bottom wall 21.

At least one of the walls, here the bottom wall 21, comprises holding elements 42 which are configured to hold the electrical and/or electronic components 4 at a distance from one another and at a distance from the walls delimiting the inner housing 3 of the box 2. By way of example, the holding elements visible in FIG. 3 consist of ribs which form a bearing surface for the electrical and/or electronic components 4 at a distance from the bottom wall 21, in order to allow a circulation of thermal control fluid between the bottom wall 21 and the electrical and/or electronic components 4.

In each of the embodiments or alternatives described with reference to FIGS. 1 to 3, the thermal control fluid discharge element 6 is separated from the bottom wall 21 by a distance less than the distance separating the thermal control fluid supply element 5 from this bottom wall 21. It should be noted, however, that without departing from the context of the invention, a reverse arrangement could be provided, with the thermal control fluid discharge element 6 which would be separated from the bottom wall 21 by a distance greater than the distance separating the thermal control fluid supply element 5 from this bottom wall 21, as long as the position of one of these ducts with respect to the bottom wall is different from the position of the other of these ducts and it is possible to arrange two similar boxes 2 side by side without the ducts 50, 60 hindering their coming together.

FIG. 4 and FIG. 5 show front views of two variant embodiments of the thermal control device 1 according to the invention, which allow this advantage in terms of bulk, by having one of the ducts, in this case the supply duct 5, which is arranged further from the bottom wall than is the discharge duct 6.

In the variant embodiment illustrated in FIG. 4, the thermal control fluid supply element 5 and the thermal control fluid discharge element 6 project from two side walls 22 of the box 2 which are opposite each other transversely.

Conversely, in the variant embodiment illustrated in FIG. 5, the thermal control fluid supply element 5 and the thermal control fluid discharge element 6 project from the same side wall 22 of the box 2.

In these FIGS. 4 and 5, the end piece 56 of the thermal control fluid supply element 5 and the end piece 66 of the thermal control fluid discharge element 6 are both in the vicinity of the same longitudinal end of the box 2. It would also be possible to envision embodiments in which the end piece 56 of the thermal control fluid supply element 5 would be in the vicinity of one of the longitudinal ends of the box 2 while the end piece 66 of the thermal control fluid discharge element 6 would be in the vicinity of the other longitudinal end of the box 2.

The particular arrangement of the thermal control fluid supply element 5 and of the thermal control fluid discharge element 6 provides facilities for storing and nesting a thermal control device according to the invention with the thermal control devices of equivalent shape which would be adjacent to it, as shown in dotted lines in FIGS. 4 and 5.

In the variant illustrated in FIG. 4, these thermal control devices may be arranged as close as possible with the fixing rim for the cover of these thermal control devices which touch one another, since the side wall of a first device on which the supply element 5 is formed is arranged facing the side wall of the second thermal control device on which the discharge element 6 is formed. The difference in vertical positioning of each type of duct thus makes it possible to slide the discharge element of a thermal control device and the supply element of a neighboring thermal control device one above the other.

In the variant illustrated in FIG. 5, these thermal control devices may be arranged as close as possible to one another, with the fixing rim for the cover of these thermal control devices which touch one another, since the side wall of a first device on which the supply element 5 and the discharge element 6 are formed one above the other is arranged facing the side wall of the second thermal control device which is free of ducts.

The fact that the thermal control fluid supply duct 5 has a cross-sectional reduction from the first longitudinal end and that the thermal control fluid discharge duct 6 has a cross-sectional enlargement from the same longitudinal end makes it possible to position, in the region formed between the two adjacent thermal control devices, the portion of the thermal control fluid supply duct 5 which has a maximum height as defined above which is therefore arranged vertically in line with the portion of the thermal control fluid discharge duct 6 which has a minimum height as defined above. Such an arrangement makes it possible in particular to prevent the end piece 56 of the first thermal control device 1 from coming into contact with the end piece 66 of the second thermal control device 1, even though they are arranged in the vicinity of the same longitudinal end of the box 2.

FIG. 6 illustrates the thermal control device 1 as a whole, with an arrangement of the end pieces of the ducts similar to that of FIG. 3. As can be seen, the box 2 comprises a base, constituted by the bottom wall 21 and the side walls 22, and the cover 23 mentioned above, the base being dimensioned to be covered by the cover.

This base forms a one-piece assembly, which is formed integrally. It is therefore not possible to separate the bottom wall 21 from the side walls 22 without damaging one or the other of these elements. The one-piece assembly can be obtained in particular by plastic injection molding, or else by additive manufacturing, and more particularly by 3D printing. In this context, the box 2 can be made of a material chosen for its thermal insulation properties. In particular, this material chosen for its thermal insulation properties can be a plastics material. Even more particularly, this plastics material can be organosheet.

The cover 23 constitutes an empty frame at its center which covers only those parts of the electrical and/or electronic components 4 which are in the vicinity of the side walls 22, thus leaving accessible the connection elements 41 of the electrical and/or electronic components 4 which are arranged on the vertical end face 40 of these electrical and/or electronic components 4. This cover 23 can be fixed to the base of the box 2 by means of screws or rivets 230, thus ensuring the sealing of the thermal control device 1.

FIG. 7 shows an alternative embodiment of the thermal control device of FIG. 6, in which the base of the box 2 is here formed by a first element comprising the bottom wall 21 and two opposite side walls 22, whereas the other two side walls 22 are produced independently and then attached to the first element. In the example illustrated, the base is constituted by the bottom wall 21 and the opposite side walls 22 which bear the thermal control fluid supply element 5 and the thermal control fluid discharge element 6, the other two side walls 22 being attached to the first element of the base 24.

At least the bottom wall 21 and the side walls 22 bearing the thermal control fluid supply element 5 and the thermal control fluid discharge element 6 can be made of metal. Advantageously, this metal may be aluminum.

In this context, the first element of the base 24 may for example be formed by stamping, which simplifies the formation of the U-shaped cross section of each of the ducts, then the other side walls are fixed by brazing to this base.

As for the embodiment shown in FIG. 6, the cover 23 constitutes an empty frame at its center which covers only those parts of the electrical and/or electronic components 4 which are in the vicinity of the side walls 22, thus leaving accessible the connection elements 41 of the electrical and/or electronic components 4 which are arranged on the vertical end of these electrical and/or electronic components 4. This cover 23 can be fixed to the base of the box 2 by means of screws or rivets 230.

An additional feature of the thermal control device 1 which can be implemented both in the embodiment of FIG. 6 and in that of FIG. 7 will now be described with reference to FIGS. 8 and 9, the box 2 having been erased in FIG. 9 to reveal the components located inside it.

The electrical and/or electronic components 4 are here separated from at least one adjacent electrical and/or electronic component by a separating member 8. Each separating member 8 therefore extends within the inner housing from one end of the box 2 to the other in a substantially transverse direction.

The separating member 8 constitutes a spacer, which makes it possible to ensure a defined distance between two adjacent electrical and/or electronic components 4. This separating member 8 may be interposed between each electrical and/or electronic component 4, or else be placed for every two electrical and/or electronic components 4, so that each electrical and/or electronic component 4 is separated from at least one other electrical and/or electronic component 4 by a separating member 8.

The separating member 8 may in particular be a corrugated metal sheet, which defines channels for the passage of thermal control fluid along each of the electrical and/or electronic components 4 arranged on either side of this separating member 8. It will thus be understood that the separating member 8 is configured to allow the thermal control fluid to pass through. The corrugations of the metal sheet of the separating member are arranged so as to allow and guide transversely the circulation of the thermal control fluid, from one side wall to the other.

According to a preferred embodiment of the invention, the electrical and/or electronic components 4 are spaced apart by a distance of between 0.2 and 1 mm by the separating member 8.

The thermal control device 1 may also comprise a sealing element 9, for example a seal, configured to be arranged between the electrical and/or electronic components and the walls. This sealing element 9 has a periphery 91 which rests on a shoulder 90 formed on the side walls 22 inside the inner housing 3, this periphery 91 thus matching the peripheral shape of the inner housing 3. The sealing element 9, for example a seal, also has transverse ribs 92, which extend across the periphery 91, from one transverse end of the sealing element 9 to the other.

This sealing element 9 is arranged in the vicinity of the vertical end face 40 of the electrical and/or electronic components 4 that faces away from the bottom wall 21. It will be understood that the position of the sealing element depends on the immersion height desired for controlling the temperature of the electrical and/or electronic components. The periphery 91, adhesively bonded against the side walls and arranged between these side walls and the electrical and/or electronic components, prevents the thermal control fluid from escaping from the inner housing, and it must at least be arranged vertically between the duct 50, 60 arranged furthest from the bottom wall and the end face 40 of the electrical and/or electronic components.

The transverse ribs 92 are configured so as to be able to be interposed between each electrical and/or electronic component 4, thus ensuring the sealing of the vertical end 40 of each electrical and/or electronic component 4.

This particular arrangement of the sealing element 9 makes it possible to prevent the thermal control fluid from leaving the inner housing 3, such a leak being detrimental both for the risk that contact of the connection elements 41 of the electrical and/or electronic components 4 with the thermal control fluid may present, and for the decrease in the level of thermal control fluid within the inner housing 3 and the loss of thermal control efficiency that would result therefrom.

The present invention thus proposes a thermal control device for an electronic system in which the electrical and/or electronic components are arranged so as to be at least partially immersed in the thermal control fluid, this device being configured, on the one hand, to allow optimized circulation of the thermal control fluid, and therefore improved thermal control, and, on the other hand, to allow compact side-by-side positioning of a plurality of thermal control devices according to the invention, whether for reasons of space requirement during transport operations or implementation of large electronic systems requiring a large number of electrical and/or electronic components. However, the present invention is not limited to the means and configurations described and illustrated herein and it also extends to any equivalent means and configuration as well as to any technically operational combination of such means, provided that a thermal control fluid supply element and a thermal control fluid discharge element are arranged on side walls of a box accommodating electrical and/or electronic components, at different distances from a bottom wall of this box.

1. A thermal control device for an electronic system, the thermal control device comprising:
a box configured to accommodate electrical and/or electronic components of the electronic system,
wherein the box comprises:
a bottom wall and side walls opposite in pairs, wherein the walls define an inner housing, wherein the inner housing is able to receive the electrical and/or electronic components, and wherein the outer faces of the side walls are defined as those facing away from the inner housing,
at least one thermal control fluid supply element,
at least one thermal control fluid discharge element,
wherein the supply element and the discharge element are in fluid communication with the inner housing,
wherein the supply element and the discharge element respectively project from one of the outer faces of the side walls of the box, and
wherein the supply element and the discharge element are arranged on the side walls at different distances from the bottom wall.

2. The thermal control device as claimed in claim 1,
wherein the supply element projects from the outer face of a side wall of the box and the discharge element projects from the outer face of an opposite side wall of the box.

3. The thermal control device as claimed in claim 1,
wherein the supply element is separated from the bottom wall by a distance greater than the distance separating the discharge element from the bottom wall.

4. The thermal control device as claimed in claim 1,
wherein the supply element comprises a duct extending mainly along a longitudinal direction,
wherein the duct is delimited longitudinally by two walls, among which a first wall, in the vicinity of a first longitudinal end of the box, bears an end piece,
wherein the duct comprises a cross section, in a plane perpendicular to the longitudinal direction, that decreases progressively away from the first wall.

5. The thermal control device as claimed in claim 4,
wherein the discharge element comprises a duct extending mainly along a longitudinal direction,
wherein the duct is delimited longitudinally by two walls, among which a first wall, in the vicinity of the first longitudinal end of the box, bears an end piece,
wherein the duct comprises a cross section, in a plane perpendicular to the longitudinal direction, that decreases progressively away from the first wall.

6. The thermal control device as claimed in claim 4,
wherein the discharge element comprises a duct extending mainly along a longitudinal direction,
wherein the duct is delimited longitudinally by two walls, among which a first wall, in the vicinity of a second longitudinal end of the box opposite the first longitudinal end of the box, bears an end piece,
wherein the duct comprises a cross section, in a plane perpendicular to the longitudinal direction, that widens progressively away from the first wall.

7. The thermal control device as claimed in claim 4,
wherein the duct forms a projection which has, in a plane perpendicular to the longitudinal direction, a U-shape open onto the inner housing of the box.

8. The thermal control device as claimed in claim 1,
wherein the box comprises a base and a cover,
wherein the base comprises the bottom wall and the side walls,
wherein the base is formed by a first element comprising the bottom wall and two opposite side walls,
wherein the other two side walls are attached and fixed to the first element.

9. An electronic system comprising:
a thermal control device as claimed in claim 1 and electrical and/or electronic components that are housed in the box of the thermal control device,
wherein the electrical and/or electronic components are separated from at least one electrical and/or electronic component by a separating member.

10. The electronic system as claimed in claim 8,
further comprising a sealing element configured to be arranged between the electrical and/or electronic components and the walls.
